(19) United States
(12) Patent Application Publication
(10) Pub. No.: US 2008/0113480 A1
(43) Pub. Date: May 15, 2008

(54) METHOD OF MANUFACTURING SEMICONDUCTOR DEVICE

(75) Inventors: Yukio NISHIDA, Tokyo (JP); Takashi Hayashi, Tokyo (JP); Tomohiro Yamashita, Tokyo (JP); Katsuyuki Horita, Tokyo (JP); Katsumi Eikyu, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Renesas Technology Corp., Tokyo (JP)

(21) Appl. No.: 11/939,941

(22) Filed: Nov. 14, 2007

(30) Foreign Application Priority Data
Nov. 15, 2006 (JP) 2006-309322

(51) Int. Cl. H01L 21/8236

(52) U.S. Cl. 438/278; 257/E21.631

(57) ABSTRACT

A semiconductor substrate is covered with a resist mask and then an opening for exposing a whole upper surface of a polysilicon gate is formed by photo lithography and dry etching. Thereafter, nitrogen ions are implanted into the polysilicon gate through the opening. Implantation energy at this time is set so that the implanted ions may not break through the polysilicon gate.

### BACKGROUND OF THE INVENTION

1. Field of the Invention

The present invention relates to a method of manufacturing a semiconductor device, in particular, to a method of manufacturing a semiconductor device having a Fully Silicided (FUSI) gate in which a gate electrode is fully silicided.

2. Description of the Background Art

In a MOS transistor as a field effect transistor, since the depletion of the gate electrode increases an effective thickness of a gate insulating film, it is desirable to suppress the depletion of the gate for improving transistor performance.

Especially, the FUSI gate in which the polysilicon gate laminated on the gate insulating film is fully silicided has a good comparability with conventional process flow, and thus is regarded as a desirable means for suppressing gate depletion.

In the formation of the FUSI gate, a polysilicon gate is formed on the gate insulating film and a source-drain extension layer and a source-drain layer are formed in a surface of a semiconductor substrate. Then, for example, a nickel film is formed so as to contact with only the upper surface of the polysilicon gate. After that, by application of heat at 300° C. for several hundreds of seconds, an Ni₂Si layer is formed in the polysilicon gate.

Then, by removing an unreacted nickel film by wet etching using compound liquid of phosphoric acid and nitric acid or the like and applying heat at 500° C. for several tens of seconds, Ni₂Si becomes NiSi and the gate electrode is fully silicided to form a transistor with the fully silicided gate electrode.

The method of forming the FUSI gate is not limited to the above-mentioned method. For example, Japanese Patent Application Laid-Open No. 2006-140319 discloses the art of performing silicidation process by implanting amorphizing germanium ions or silicon ions into the polysilicon gate for amorphization in order to simplify silicidation.

The MOS transistor having the FUSI gate thus formed has the following problems.

A first problem is that it is difficult to hold silicide composition in the FUSI gate constant and thus, transistor performance of the MOS transistor having the FUSI gate becomes unstable.

Although various compositions such as NiSi, Ni₂Si, Ni₃₁Si₁₂ and Ni₃Si as nickel silicide exist, to stabilize transistor performance, it is desirable to stably form a particular composition.

However, since such composition varied depending on gate length and the same gate length does not necessarily result in the same composition, in fact, it is difficult to stabilize transistor performance.

A second problem is that it is difficult to intentionally change silicide composition in one wafer.

For example, A. Lauwers et al., “CMOS Integration of Dual Work Function Phase Controlled Ni FUSI with Simultaneous Silicidation of NMOS (NiSi) and PMOS (Ni-rich silicide) Gates on HfSiON” IEDM 2005, pp. 661-664 reports that, when nickel silicide is used as silicide and a high dielectric film such as HfSiON (hafnium silicate containing nitrogen) is used as the gate insulating film, a threshold value (Vth) of the transistor varies depending on what composition constitutes nickel silicide.

That is, in a P-channel MOS transistor, the threshold value becomes lower as the amount of nickel is increased, while in an N-channel MOS transistor, the threshold value becomes higher as the amount of nickel is increased. Thus, it is preferred that a gate of a small amount of nickel is formed in an NMOS region where the N-channel MOS transistor is formed and a gate of a large amount of nickel is formed in a PMOS region where the P-channel MOS transistor.

Silicidation is generated by the reaction of the nickel layer laminated on the polysilicon gate with silicon in the polysilicon gate by heat treatment. Actually, since nickel in the vicinity of the gate moves into the gate by diffusion and reacts with silicon, a smaller gate tends to react with more nickel.

For this reason, A. Lauwers et al., “CMOS Integration of Dual Work Function Phase Controlled Ni FUSI with Simultaneous Silicidation of NMOS (NiSi) and PMOS (Ni-rich silicide) Gates on HfSiON” IEDM 2005, pp. 661-664 discloses the art of reducing volume by making the height of the polysilicon gate in the PMOS region smaller than that of the polysilicon gate in the NMOS region to relatively increasing the amount of nickel.

As described above, the MOS transistor having the FUSI gate has the problems that it is difficult to hold silicide composition in the FUSI gate constant and thus, transistor performance becomes unstable and that it is difficult to intentionally change silicide composition in one wafer.

### SUMMARY OF THE INVENTION

An object of the present invention is to provide a semiconductor device having MOS transistors with a uniform silicide composition in a FUSI gate to realize stable transistor performance, and a semiconductor device having MOS transistors with different silicide compositions in one wafer.

In an aspect of a method of manufacturing a semiconductor device according to the present invention, a semiconductor substrate is covered with a resist mask, and then an opening for exposing a whole upper surface of a polysilicon gate in an NMOS region is formed by photo lithography and dry etching. Thereafter, nitrogen ions are implanted into the polysilicon gate through the opening. Implantation energy at this time is set so that the implanted ions may not break through the polysilicon gate. Then, after the resist mask is removed, a nickel film is formed so as to cover the semiconductor substrate. By application of heat at 300° C. for several hundreds of seconds, a nickel silicide layer is formed on the polysilicon gate. After an unreacted nickel film is removed, by application of heat at 500° C. for several tens of seconds, the polysilicon gate is fully silicided.

According to the above-mentioned manufacturing method, since nickel is prevented from diffusing in the polysilicon gate containing nitrogen, when fully silicided by subsequent heat treatment, the fully silicided gate contains a small amount of nickel per unit volume.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 9 are sectional views showing a method of manufacturing a semiconductor device in accordance with First Embodiment of the present invention;

FIGS. 10 to 12 are sectional views showing a method of manufacturing a semiconductor device in accordance with Second Embodiment of the present invention;

FIGS. 13 to 17 are sectional views showing a method of manufacturing a semiconductor device in accordance with Third Embodiment of the present invention;

FIGS. 18 to 21 are sectional views showing a method of manufacturing a semiconductor device in accordance with Fourth Embodiment of the present invention; and

FIGS. 22 to 24 are sectional views showing a method of manufacturing a semiconductor device in accordance with Fifth Embodiment of the present invention.

These and other objects, features, aspects and advantages of the present invention will become more apparent from the following detailed description of the present invention when taken in conjunction with the accompanying drawings.

### DESCRIPTION OF THE PREFERRED EMBODIMENTS

A term “MOS” is formerly used as a laminate structure of metal/oxide/semiconductor and is an abbreviation of Metal-Oxide-Semiconductor. However, especially in a field effect transistor having MOS structure (hereinafter, referred to as merely a “MOS transistor”), with integration and improvement in manufacturing process in recent years, materials for the gate insulating film and the gate electrode have been improved.

For example, in the MOS transistor, mainly to form source-drain in a self-alignment process, polysilicon in place of metal has been adopted as a material for the gate electrode. Furthermore, to improve electric characteristics, high dielectric constant materials are adopted as a material for the gate insulating film. However, the material is not necessarily limited to oxides.

Therefore, the term “MOS” is not necessarily applied only to the laminate structure of metal/oxide/semiconductor and this also applies to this specification. That is, in light of technical common sense, “MOS” means the abbreviation generated by the root of the term as well as a laminate structure of conductor/insulator/semiconductor.

### A. First Embodiment

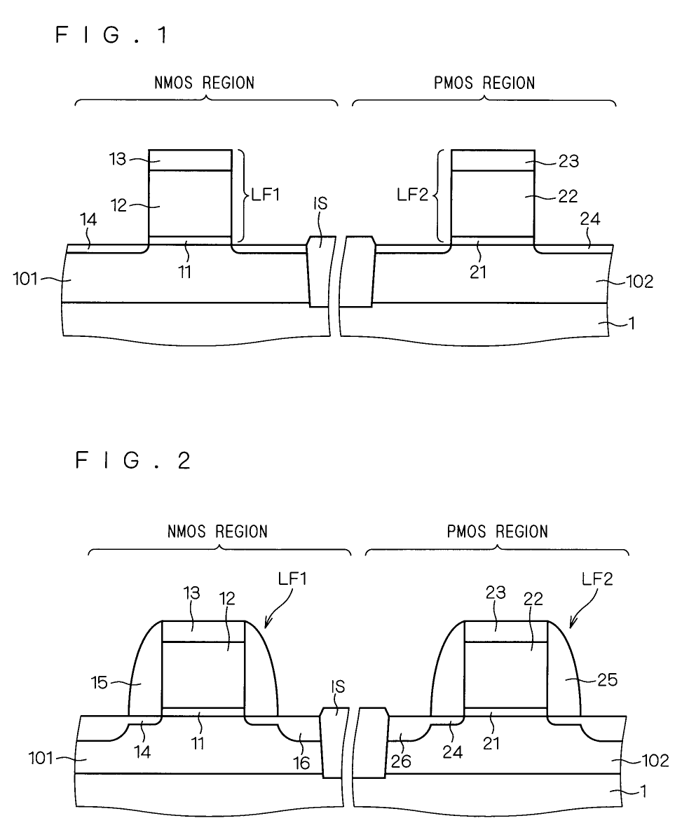

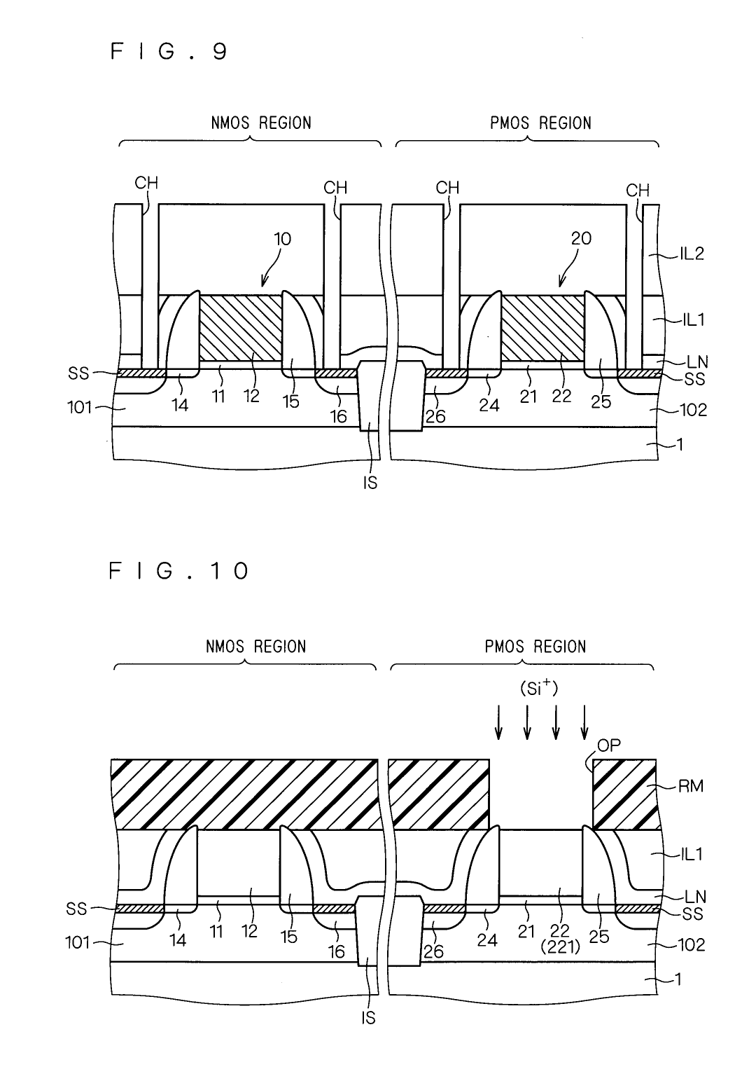

As First Embodiment of the present invention, a manufacturing process in a method of manufacturing a semiconductor device having an N-channel MOS transistor (NMOS transistor) 10 and a P-channel MOS transistor (PMOS transistor) 20 on a common semiconductor substrate 1 will be described with reference to FIG. 1 to FIG. 9. Structure of the NMOS transistor 10 and the PMOS transistor 20 is shown in FIG. 9.

### <A-1. Manufacturing Process>

First, as shown in FIG. 1, the semiconductor substrate 1 such as a silicon substrate is prepared and a element isolation insulating film IS with (Shallow Trench Isolation) structure is selectively formed in a main surface of the substrate 1 by using well-known technique to define an active region where semiconductor elements are formed. The active region includes an NMOS region (first region) where the NMOS transistor is formed and a PMOS region (second region) where the PMOS transistor is formed.

Then, a P-type impurity such as boron (B) is introduced into only the NMOS region to form a P well 101 in the surface of the semiconductor substrate 1. An N-type impurity such as phosphorus (P) is introduced into only the PMOS region to form an N well 102 in the surface of the semiconductor substrate 1.

Subsequently, a metal oxide film and a silicate film such as an HfO₂ film and an HfSiON film are formed on the semiconductor substrate 1 by using a CVD (chemical vapor deposition) method or a PVD (physical vapor deposition) method. The HfO₂ film and the HfSiON film are a so-called a High-k film (high dielectric film). By using these films as the gate insulating film, the effective thickness of the gate insulating film can be increased.

Next, a polysilicon layer is fully formed on the high dielectric film by using, for example, the CVD method. Here, the thickness of the polysilicon layer is set to about 100 nm.

Next, a silicon nitride film is formed on the polysilicon layer by using, for example, the CVD method and then, the silicon nitride film, the polysilicon layer and the gate insulating film are sequentially and selectively removed by photo lithography and dry etching. In this manner, a laminated film LF1 including the gate insulating film 11, a polysilicon gate 12 and a gate hard mask 13 is formed in the NMOS region and a laminated film LF2 including a gate insulating film 21, a polysilicon gate 22 and a gate hard mask 23 is formed in the PMOS region.

After that, using the laminated film LF1 as an implantation mask, ions of the N-type impurity such as arsenic are implanted in the NMOS region with implantation energy of 2.0 to 6.0 keV so that dosage may be 3×10¹⁴ to 3×10¹⁵/cm², thereby forming a source-drain extension layer 14 in the surface of the semiconductor substrate 1 outside of the side face of the laminated film LF1.

Using the laminated film LF2 as an implantation mask, ions of the P-type impurity such as boron are implanted in the PMOS region with implantation energy of 0.3 to 0.8 keV so that dosage may be 1×10¹⁴ to 1×10¹⁵/cm², thereby forming a source-drain extension layer 24 in the surface of the semiconductor substrate 1 outside of the side face of the laminated film LF2.

Next, at a step shown in FIG. 2, a silicon oxide film is formed by using, for example, the CVD method so as to cover the semiconductor substrate 1 including the laminated films LF1 and LF2 and then, the silicon oxide film is removed by dry etching to form side-wall insulating films 15 and 25 on the side faces of the laminated films LF1 and LF2, respectively. The side-wall insulating films 15 and 25 may be each formed of a silicon nitride film. In this case, the side faces of the laminated films LF1 and LF2 are covered with a thin silicon oxide film in advance and the silicon nitride film is laminated thereon.

Using the laminated film LF1 on which the side-wall insulating film 15 is formed as an implantation mask, ions of the N-type impurity such as arsenic are implanted in the NMOS region with implantation energy of 5 to 20 keV so that dosage may be 3×10¹⁵ to 6×10¹⁵/cm², thereby forming a source-drain layer 16 in the surface of the semiconductor substrate 1 outside of the side face of the side-wall insulating film 15.

Using the laminated film LF2 on which the side-wall insulating film 25 is formed as an implantation mask, ions of the P-type impurity such as boron are implanted in the PMOS region with implantation energy of 0.8 to 4 keV so that dosage may be 1×10¹⁵ to 6×10¹⁵/cm², thereby forming a source-drain layer 26 in the surface of the semiconductor substrate 1 outside of the side face of the side-wall insulating film 25.

Next, a nickel film is formed by using a sputtering method so as to cover the semiconductor substrate 1 and is reacted with silicon for silicide reaction by heat treatment.

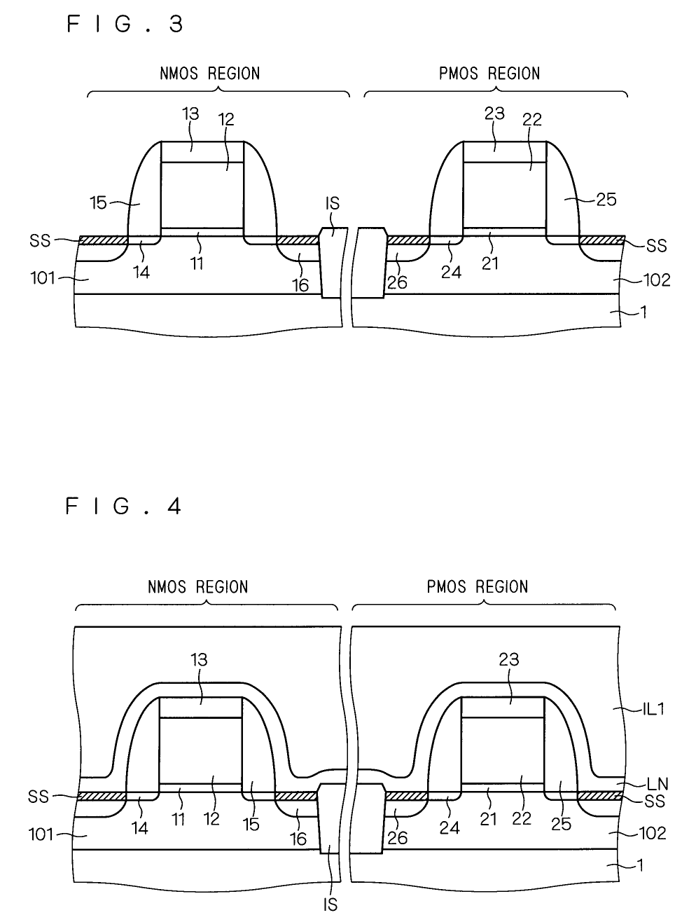

Since silicide reaction does not occurs between silicon and the insulating film, an unreacted Ni film remains in the side-wall insulating films 15 and 25 and the gate hard masks 13 and 23. By removing the unreacted Ni film, as shown in FIG. 3, a silicide layer SS is formed on only the source-drain layers 16 and 26.

Next, at a step shown in FIG. 4, a silicon nitride film having the thickness of about 30 nm is laminated by using, for example, an Atomic Layer Deposition (ALD) method so as to cover the semiconductor substrate 1 to form an interlayer liner film LN.

Subsequently, a silicon oxide film having the thickness of about 500 nm is laminated by using, for example, a high density plasma CVD method so as to cover the semiconductor substrate 1 to form an interlayer insulating film IL1.

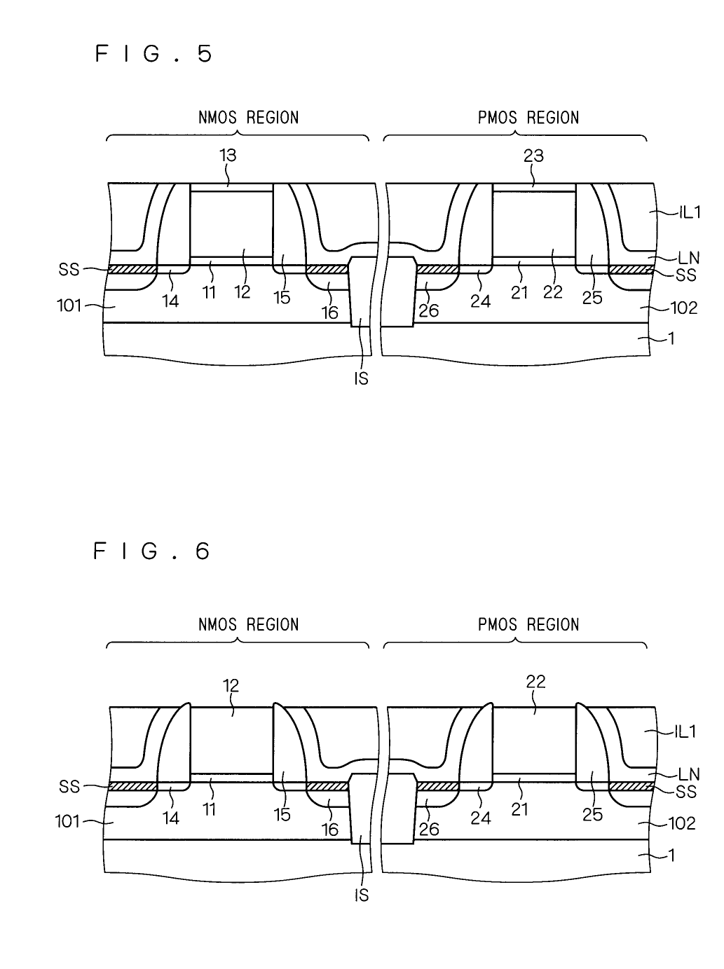

Next, at a step shown in FIG. 5, by CMP (Chemical Mechanical Polishing) processing using the gate hard masks 13 and 23 as stopper, the interlayer insulating film IL1 and the interlayer liner film LN on the polysilicon gates 12 and 22 are removed. At this time, the gate hard masks 13 and 23 slightly remain on the polysilicon gates 12 and 22.

Next, at a step shown in FIG. 6, by removing the gate hard masks 13 and 23 remaining on the polysilicon gates 12 and 22 through dry etching of removing the silicon nitride film, the polysilicon gates 12 and 22 are exposed. Traces of the removed gate hard masks 13 and 23 become recess portions.

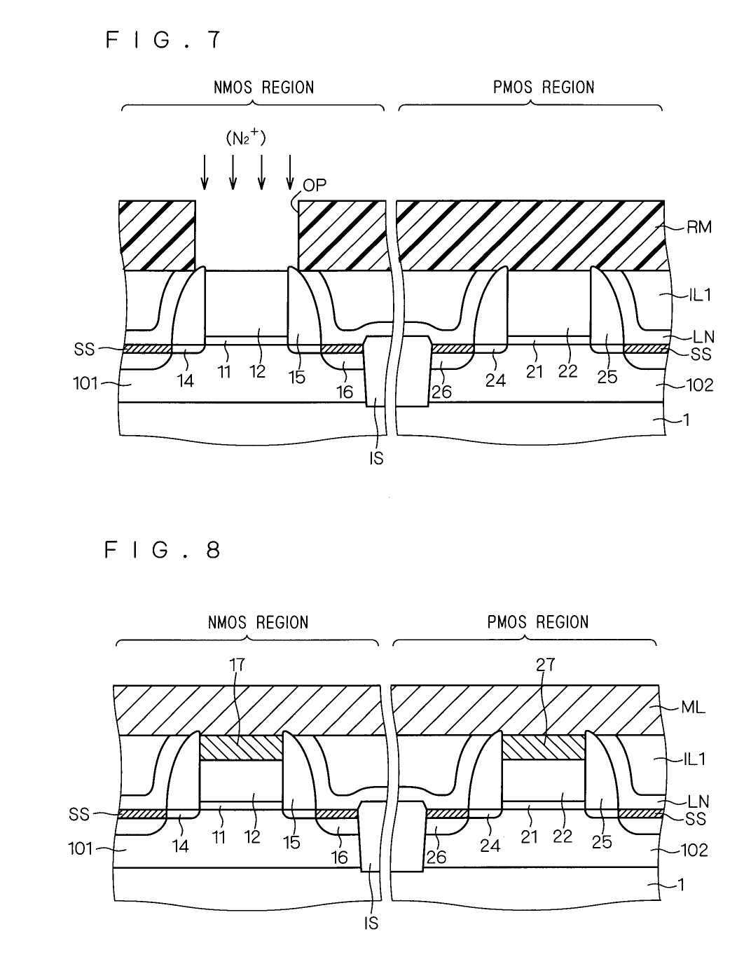

Next, at a step shown in FIG. 7, after the semiconductor substrate 1 is covered with a resist mask RM, an opening OP for exposing the whole upper surface of the polysilicon gate 12 is formed by photo lithography and dry etching.

Then, nitrogen ions are implanted into the polysilicon gate 12 through the opening OP. The implantation energy at this time is set so that the implanted ions may not break through the polysilicon gate 12. For example, in a case of nitrogen molecule (N₂) ions, the implantation energy is set to 10 keV and the dosage is set to about 1×10¹⁵/cm².

In a case of nitrogen molecule (N₂) ions, when the implantation energy is 10 keV, implantation peak position is about 10 nm in depth. Thus, the implanted ions cannot break through the polysilicon gate 12 having the thickness of 100 nm. In place of N₂ ions, nitrogen (N) ions, Oxygen (O) ions or germanium (Ge) ions may be used. These ions may not be implanted deeper than a half of height of the polysilicon gate 12. Desirably, the implantation energy is set so that the implantation peak position is located at about one fifth of height of the polysilicon gate 12.

As the dosage of N₂ ions is increased, the effect of suppressing diffusion of nickel described later is improved. However, an effective range is 5×10¹⁴ to 1×10¹⁶/cm².

By introducing nitrogen through ion implantation in this manner, an introduction region can be advantageously set conveniently and arbitrarily according to a resist mask pattern.

Next, after the resist mask RM is removed, at a step shown in FIG. 8, a nickel film ML having a thickness of about 200 nm is formed by using, for example, the sputtering method, so as to cover the semiconductor substrate 1 and heated at 300° C. for about several hundreds of seconds to form nickel silicide layers 17 and 27 mainly composed of Ni₂Si on the polysilicon gates 12 and 22, respectively.

At this time, since nickel is prevented from diffusing in the polysilicon gate 12 containing nitrogen, the nickel silicide layer 17 formed on the polysilicon gate 12 is thinner than the nickel silicide layer 27 formed on the polysilicon gate 22 containing no nitrogen.

Next, the unreacted nickel film ML is removed by wet etching using compound liquid of phosphoric acid and nitric acid or the like.

Then, by application of heat treatment at 500° C. for several hundreds of seconds, nickel in the nickel silicide layers 17 and 27 diffuses and the polysilicon gates 12 and 22 are silicided as a whole. As shown in FIG. 9, the nickel silicide layers 17 and 27 become FUSI gates 171 and 271, respectively, to complete the NMOS transistor 10 and the PMOS transistor 20.

At this time, due to the thick nickel silicide layer 27, the amount of nickel per unit volume in the FUSI gate 271 is larger than that in the FUSI gate 171.

Subsequently, a silicon oxide film having the thickness of about 500 nm is laminated by using, for example, a high density plasma CVD method so as to cover the semiconductor substrate 1 to form an interlayer insulating film IL2.

Then, a plurality of contact openings CH reaching the silicide layers SS on the source-drain layers 16 and 26 through the interlayer insulating films IL2 and IL1 are formed by photo lithography and dry etching. At this time, although the contact openings CH are formed to reach the FUSI gates 171 and 271 as well, they are not shown in FIG. 9.

Thereafter, contact parts are formed by filling a conductive layer into the contact openings CH according to a conventional method and a wiring layer is patterned on the interlayer insulating film IL2 so as to the contact part to obtain a desired semiconductor device.

### <A-2. Effects>

According to the method of manufacturing a semiconductor device in accordance with First Embodiment, in the manufacturing process of the NMOS transistor 10, nitrogen ions are implanted into the polysilicon gate 12 and then, the nickel silicide layer 17 mainly composed of Ni₂Si is formed on the polysilicon gate 12.

Since nickel is prevented from diffusing in the polysilicon gate 12 containing nitrogen, the nickel silicide layer 17 formed on the polysilicon gate 12 is thinner than the nickel silicide layer 27 formed on the polysilicon gate 22 containing no nitrogen. When the silicide layer 17 is fully silicided by subsequent heat treatment, the FUSI gate 171 has a small amount of nickel per unit volume. For example, even in a case of Ni₂Si if nitrogen is not contained, the existence of nitrogen results in NiSi.

As to the effect of suppressing the diffusion of nickel by nitrogen implantation, an experiment of inventors confirms that the nickel concentration in the polysilicon gate with nitrogen implantation is reduced to about 72% of the nickel concentration without nitrogen implantation.

By composing the FUSI gate 171 to have a small amount of nickel per unit volume in this manner, a threshold value (Vth) of the NMOS transistor 10 can be made low, and by excluding nitrogen from the polysilicon gate 22, the FUSI gate 271 can contain a large amount of nickel per unit volume, thereby making a threshold (Vth) of the PMOS transistor 20 low.

The effect of suppressing the diffusion of nickel in polysilicon can be also obtained by implantation of boron (B) or fluorine (F) other than nitrogen and germanium.

Here, in a transistor using a High-k film as the gate insulating film and a FUSI gate as a gate electrode, if impurity of the same conductive type as the source-drain layer is introduced by so-called gate implantation, no effect brings about. Thus, since no trouble occurs even when a large amount of impurity of a different conductive type from the source-drain layer is introduced, the conductive type of ions implanted for suppressing the diffusion of silicide metal need not be considered.

When N₂ ions and Ge ions which are heavier than B ions and F ions are implanted, polysilicon can be amorphized and silicide metal is uniformly diffused, thereby suppressing variation in transistor performance.

### B. Second Embodiment

As Second Embodiment of the present invention, a manufacturing process in a method of manufacturing a semiconductor device having an N-channel MOS transistor 10A and a P-channel MOS transistor 20A on the common semiconductor substrate 1 will be described with reference to FIG. 10 to FIG. 12. Structure of the NMOS transistor 10A and the PMOS transistor 20A is shown in FIG. 12.

### <B-1. Manufacturing Process>

Through the steps described in First Embodiment shown in FIG. 1 to FIG. 6, by removing the gate hard masks 13 and 23 from the polysilicon gates 12 and 22, the polysilicon gates 12 and 22 are exposed.

Next, at a step shown in FIG. 10, the semiconductor substrate 1 is covered with the resist mask RM and then, the opening OP for exposing the whole upper surface of the polysilicon gate 22 is formed by photo lithography and dry etching.

Then, by implanting silicon ions into the polysilicon gate 22 through the opening OP, the polysilicon gate 22 is amorphized to an amorphous silicon gate 221.

The implantation energy at this time is set so that the implanted ions may not break through the polysilicon gate 22. For example, in a case of silicon ions, the implantation energy is set to about 5 keV and the dosage is set to about 2×10¹⁵/cm². When the implantation energy is 5 keV, implantation peak position is about 7 nm in depth. Thus, the implanted ions cannot break through the polysilicon gate 22 having the thickness of 100 nm. In place of silicon, phosphorus (P), argon (Ar), germanium (Ge), arsenic (As), stibium (Sb) and indium (In) may be used. These ions may not be implanted deeper than a half of height of the polysilicon gate 22. Desirably, the implantation energy is set so that the implantation peak position is located at about one fifth of height of the polysilicon gate 22.

By introducing silicon through ion implantation in this manner, an introduction region can be advantageously set conveniently and arbitrarily according to a resist mask pattern.

As dosage of silicon ions is increased, the effect of accelerating amorphization of the polysilicon gate is improved and the effective range is 5×10¹⁴ to 1×10¹⁶/cm².

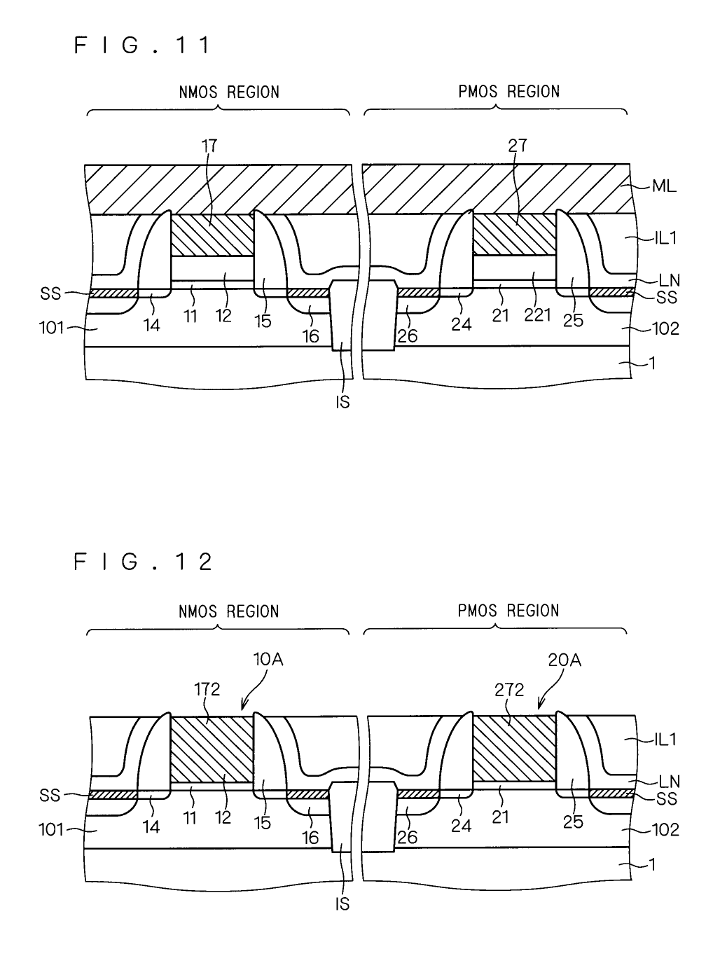

Next, after the resist mask RM is removed, at a step shown in FIG. 11, a nickel film ML having a thickness of about 200 nm is formed by using, for example, the sputtering method, so as to cover the semiconductor substrate 1 and heated at 300° C. for about several hundreds of seconds to form nickel silicide layers 17 and 27 mainly composed of Ni₂Si on the polysilicon gate 12 and the amorphous silicon 221, respectively.

Next, the unreacted nickel film ML is removed by wet etching using compound liquid of phosphoric acid and nitric acid or the like.

Then, by application of heat treatment at 500° C. for several tens of seconds, nickel in the nickel silicide layers 17 and 27 diffuses and the polysilicon gate 12 and the amorphous silicon gate 221 are silicided as a whole. As shown in FIG. 12, the nickel silicide layers 17 and 27 become FUSI gates 172 and 272, respectively, to complete the NMOS transistor 10A and the PMOS transistor 20A. Since subsequent steps are the same as the steps described with reference to FIG. 9, description thereof is not repeated.

### <B-2. Effects>

According to the method of manufacturing a semiconductor device in accordance with Second Embodiment, in the manufacturing process of the PMOS transistor 20A, silicon ions are implanted into the polysilicon gate 22 to form an amorphous silicon gate 221, and a nickel silicide layer 27 mainly composed of Ni₂Si is formed on the amorphous silicon gate 221.

In a case of polysilicon, diffusion state of silicide metal such as nickel can vary due to ununiformity of crystalline interface. However, since the silicide metal is uniformly diffused because of amorphization caused by ion implantation, variation in transistor performance is suppressed.

Polysilicon can be also amorphized by implanting ions of P, Ar, Ge, As, Sb or In. Since this ion implantation is different from doping for setting the conductive type of the polysilicon gate and serves to control the diffusion of silicide metal, the implantation is performed immediately before the fully silicided process.

In a transistor using a High-k film as the gate insulating film and a FUSI gate as a gate electrode, if impurity of the same conductive type as the source-drain layer is introduced by so-called gate implantation, no effect brings about. Thus, since no trouble occurs even when a large amount of impurity of a different conductive type from the source-drain layer is introduced, the conductive type of ions implanted for amorphization need not be considered.

### C. Third Embodiment

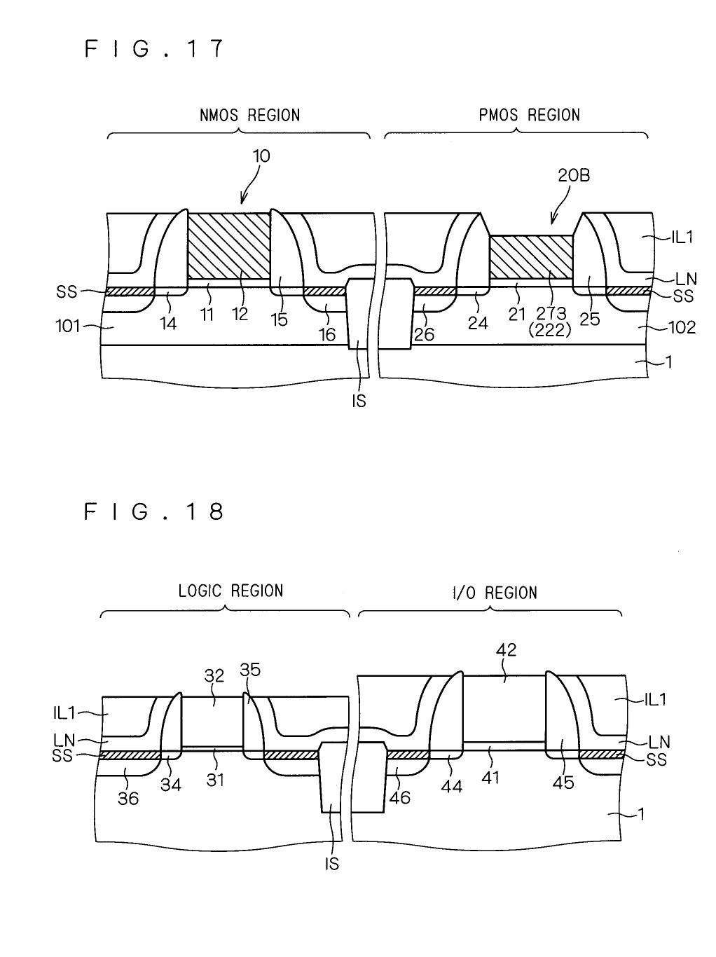

As Third Embodiment of the present invention, a manufacturing process in a method of manufacturing a semiconductor device having the NMOS transistor 10 and a PMOS transistor 20B on the common semiconductor substrate 1 will be described with reference to FIG. 22 to FIG. 24. Structure of the NMOS transistor 10 and the PMOS transistor 20B is shown in FIG. 17.

### <C-1. Manufacturing Process>

Through the steps described in First Embodiment shown in FIG. 1 to FIG. 6, by removing the gate hard masks 13 and 23 from the polysilicon gates 12 and 22, the polysilicon gates 12 and 22 are exposed.

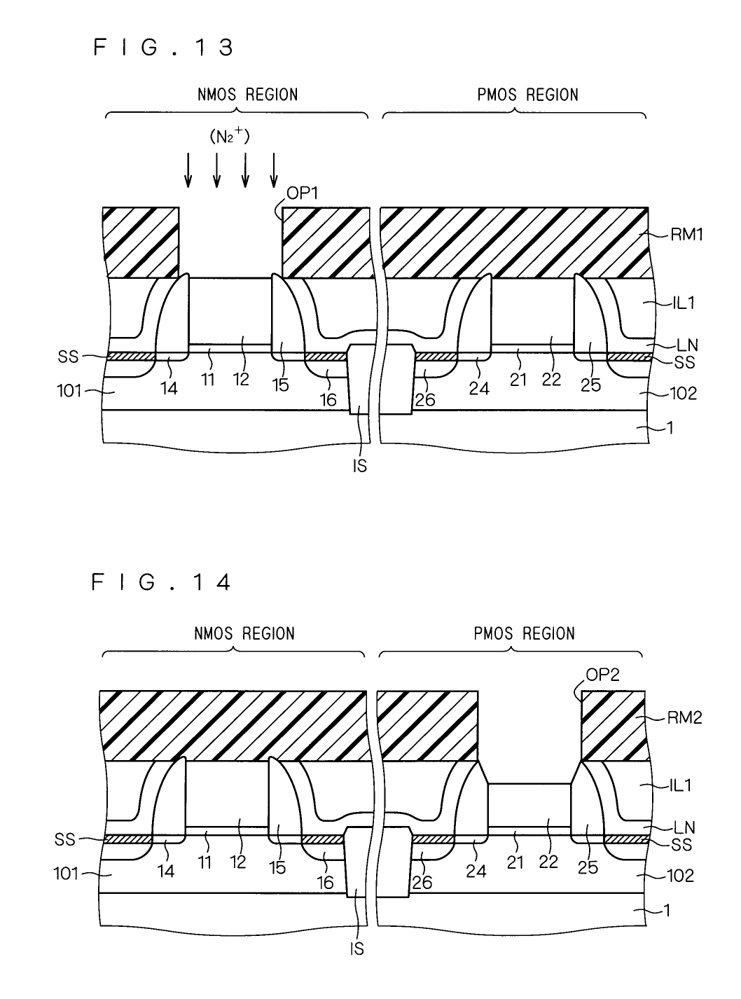

Next, at a step shown in FIG. 13, the semiconductor substrate 1 is covered with the resist mask RM1 and then, the opening OP for exposing the whole upper surface of the polysilicon gate 12 is formed by photo lithography and dry etching.

Then, nitrogen ions are implanted into the polysilicon gate 12 through an opening OP1. Implantation conditions at this time are the same as those implantation conditions of nitrogen ions described in First Embodiment with reference to FIG. 7. In place of N₂ ions, nitrogen (N) ions or germanium (Ge) ions may be implanted.

After the resist mask RM1 is removed, at a step shown in FIG. 14, the semiconductor substrate 1 is covered with a resist mask RM2 and an opening OP2 for exposing the whole upper surface of the polysilicon gate 22 is exposed by photo lithography and dry etching.

Subsequently, by dry etching for removing polysilicon, the polysilicon gate 22 is etched by about 40 nm. Thus, the height of the polysilicon gate 22 becomes about 60 nm, which is smaller than 100 nm as the height of the polysilicon gate 12.

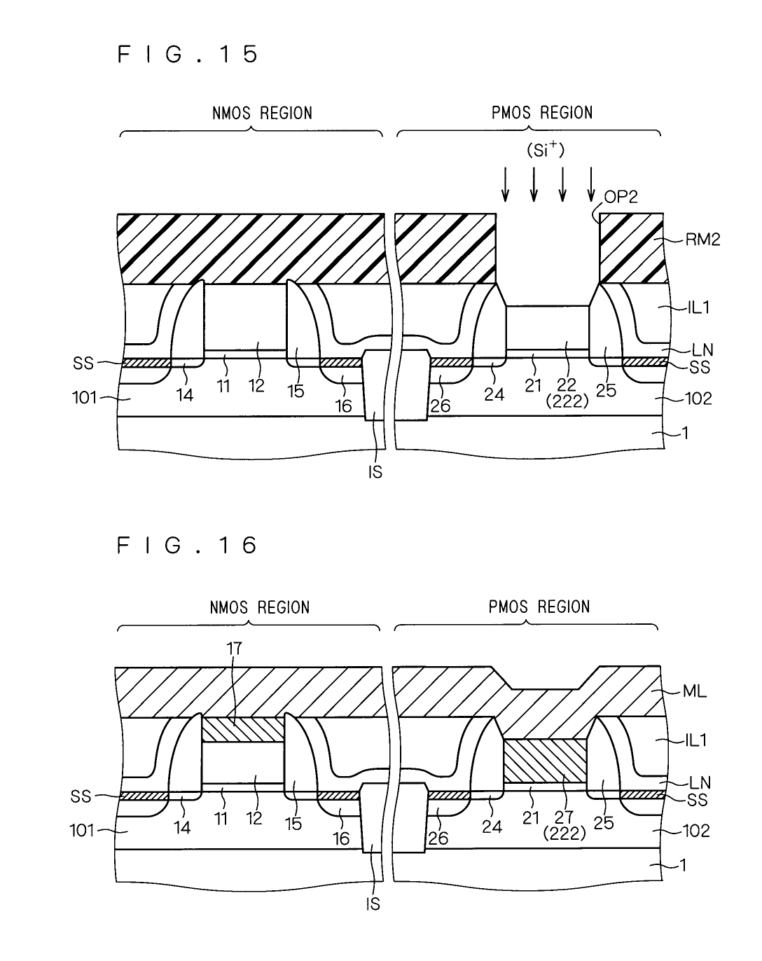

Then, at a step shown in FIG. 15, by implanting silicon ions into the polysilicon gate 22 through the opening OP2, the polysilicon gate 22 is amorphized to form an amorphous silicon gate 222. Implantation conditions at this time are the same as those implantation conditions of silicon ions described in Second Embodiment with reference to FIG. 10. In place of silicon, P, Ar, Ge, arsenic, Sb or In may be used.

Although Ge has the effect of suppressing the diffusion of silicide metal in polysilicon, the effect of accelerating amorphization appears more intensely.

Next, after the resist mask RM2 is removed, at a step shown in FIG. 16, a nickel film ML having a thickness of about 200 nm is formed by using, for example, the sputtering method, so as to cover the semiconductor substrate 1 and heated at 300° C. for about several hundreds of seconds to form nickel silicide layer 17 mainly composed of Ni₂Si on the polysilicon gate 12. Since the height of the amorphous silicon gate 222 is reduced to about 60 nm, the almost whole of the amorphous silicon gate 222 becomes the nickel silicide layer 27 mainly composed of Ni₂Si.

Next, the unreacted nickel film ML is removed by wet etching using compound liquid of phosphoric acid and nitric acid or the like.

Then, by application of heat at 500° C. for several tens of seconds, nickel in the nickel silicide layers 17 and 27 diffuses and whole of the polysilicon gate 12 and the amorphous silicon gate 222 are silicided. As a result, the polysilicon gate 12 and as shown in FIG. 17, the amorphous silicon gate 222 become FUSI gates 171 and 273, respectively, to form the NMOS transistor 10 and the PMOS transistor 20B.

At this time, due to the thick nickel silicide layer 27, the amount of nickel per unit volume in the FUSI gate 273 is larger than that in the FUSI gate 171.

### <C-2. Effects>

According to the method of manufacturing a semiconductor device in accordance with Third Embodiment as described above, in the manufacturing process of the NMOS transistor 10, nitrogen ions are implanted into the polysilicon gate 12 and then the nickel silicide layer 17 mainly composed of Ni₂Si is formed on the polysilicon gate 12.

Since nickel is prevented from diffusing in the polysilicon gate 12 containing nitrogen, the nickel silicide layer 17 is thinner than the nickel silicide layer 27 of the amorphous silicon gate 222 containing no nitrogen. When fully silicided by subsequent heat treatment, the FUSI gate 171 has a small amount of nickel per unit volume.

On the other hand, since the amorphous silicon gate 222 having the height of about 60 nm is very thin and the almost whole of the gate 222 becomes the nickel silicide layer 27, when fully silicided by subsequent heat treatment, the FUSI gate 273 has a larger amount of nickel per unit volume than the FUSI gate 171.

By composing the FUSI gate 171 to have a small amount of nickel in this manner, a threshold value (Vth) of the NMOS transistor 10 can be made low, and by excluding nitrogen from the polysilicon gate 22, the FUSI gate 273 can contain a large amount of nickel, thereby making a threshold (Vth) of the PMOS transistor 20B low.

In the manufacturing process of the PMOS transistor 20B, silicon ions are implanted into the polysilicon gate 22 to form an amorphous silicon gate 222. In a case of polysilicon, diffusion state of silicide metal such as nickel can vary due to ununiformity of crystalline interface. However, since the silicide metal is uniformly diffused because of amorphization caused by ion implantation, variation in transistor performance is suppressed.

### D. Fourth Embodiment

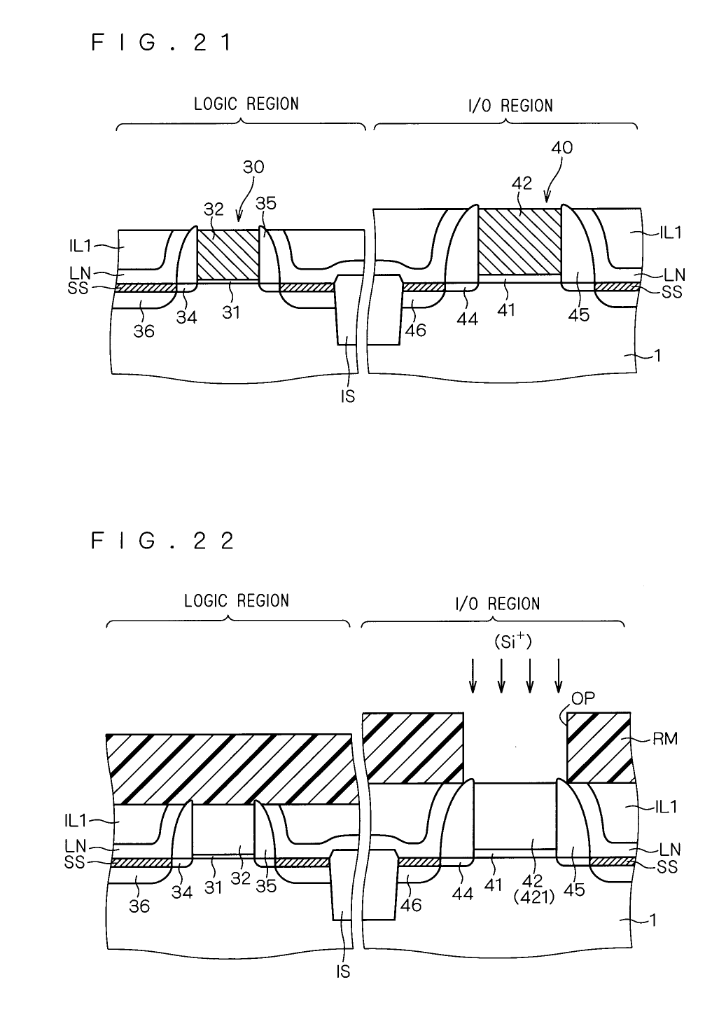

As Fourth Embodiment of the present invention, a manufacturing process in a method of manufacturing a semiconductor device having MOS transistors 30 and 40 of different gate sizes on the common semiconductor substrate 1 will be described with reference to FIG. 18 to FIG. 21. Structure of the MOS transistors 30 and 40 is shown in FIG. 21.

### <D-1. Manufacturing Process>

In FIG. 18 to FIG. 21, the semiconductor substrate 1 is divided into a logic region (first region) where a logic circuit is formed and an I/O region (second region) where an input/output circuit is disposed. Steps for forming a MOS transistor 30 having a thin gate insulating film and a short gate length (FIG. 21) in the logic region and a MOS transistor 40 having a thick gate insulating film and a long gate length (FIG. 21) in the I/O region are shown in these figures.

In the logic region shown in FIG. 18, for example, a polysilicon gate 32 is disposed on a two-layer gate insulating film 31 in which an HfSiON film is laminated on an SiO₂ film, and a side-wall insulating film 35 formed of, for example, a silicon oxide film is disposed on side faces of the gate insulating film 31 and the polysilicon gate 32.

A source-drain extension layer 34 is disposed in the surface of the semiconductor substrate 1 outside of the side face of the polysilicon gate 32 and a source-drain layer 36 is disposed in the surface of the semiconductor substrate 1 outside of the side face of the side-wall insulating film 35 to constitute transistor structure. A silicide layer SS is disposed on the source-drain layer 36.

The conductive type of the source-drain extension layer 34 and the source-drain layer 36 is not specifically limited.

In the I/O region, a polysilicon gate 42 is disposed on a two-layer gate insulating film 41 in which an HfSiON film is laminated on an SiO₂ film, and a side-wall insulating film 55 formed of, for example, a silicon oxide film is disposed on side faces of the gate insulating film 41 and the polysilicon gate 42.

A source-drain extension layer 44 is disposed on the surface of the semiconductor substrate 1 outside of the side face of the polysilicon gate 42 and a source-drain layer 46 is disposed on the surface of the semiconductor substrate 1 outside of the side face of the side-wall insulating film 45 to constitute transistor structure. A silicide layer SS is disposed on the source-drain layer 46.

The conductive type of the source-drain extension layer 44 and the source-drain layer 46 is not specifically limited.

The gate insulating film 31 is thinner than the gate insulating film 41 and the gate length of the polysilicon gate 32 is smaller than that of the polysilicon gate 42. The height of the polysilicon gate 32 is smaller than that of the polysilicon gate 42. This is due to that driving voltage of the MOS transistor formed in the logic region is lower than that of the MOS transistor formed in the I/O region. In addition, since necessary current driving force is small, gate width not shown is set to be small.

Since the structure shown in FIG. 18 is obtained by the same steps as the steps described in First Embodiment with reference to FIG. 1 to FIG. 6, description thereof is not repeated.

In FIG. 18, the interlayer liner film LN and the interlayer insulating film IL1 above the polysilicon gates 32 and 42 are removed and gate hard masks (not shown) disposed on the polysilicon gates 32 and 42 are removed, so that the polysilicon gates 32 and 42 are exposed. Traces of the removed gate hard mask become hollow.

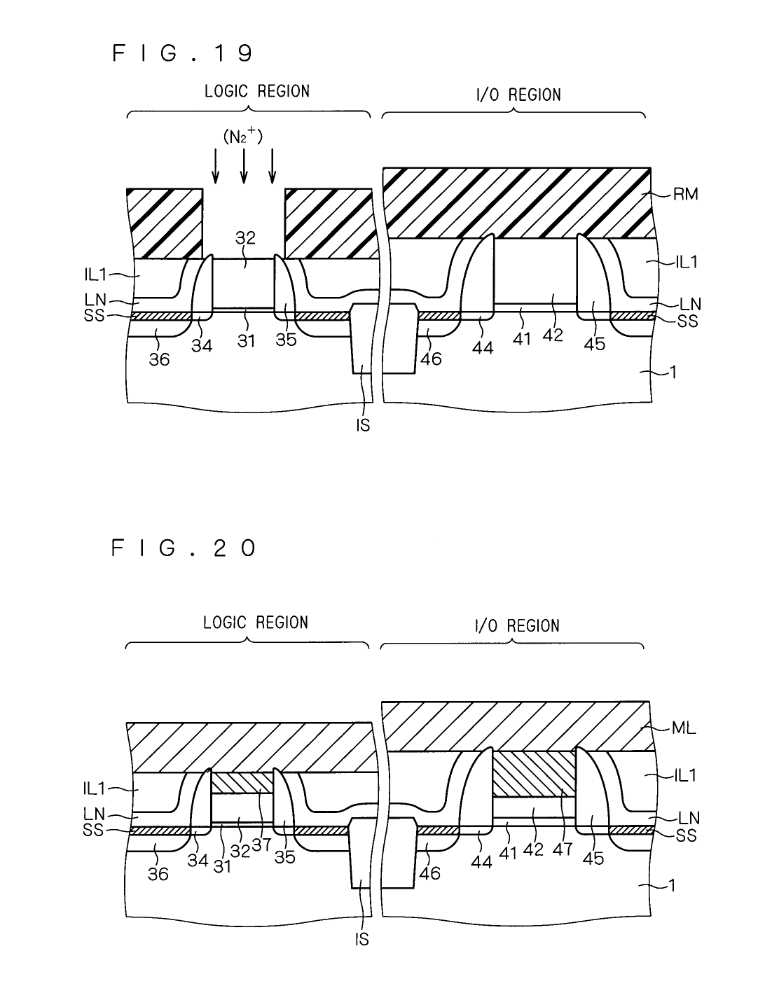

At a step shown in FIG. 19, the semiconductor substrate 1 is covered with a resist mask RM and an opening OP for exposing the whole upper surface of the polysilicon gate 32 is formed by photo lithography and dry etching.

Then, nitrogen ions are implanted into the polysilicon gate 32 through the opening OP. The implantation energy at this time is set so that the implanted ions may not break through the polysilicon gate 32. For example, when the height of the polysilicon gate 42 is about 100 nm, as long as the height of the polysilicon gate 32 is about half of that of the polysilicon gate 42, even if nitrogen molecule (N₂) ions are implanted with energy of about 10 keV, implanted ions cannot break through the polysilicon gate 32.

In place of N₂ ions, nitrogen (N) ions, oxygen (O) ions and germanium (Ge) ions may be used. Any ion may not be implanted deeper from a half of the height of the polysilicon gate 32. Desirably, the implantation energy is set so that the implantation peak position is located at about one fifth of the height of the polysilicon gate 32. The effective range of dosage of N₂ ions is 5×10¹⁴ to 1×10¹⁶/cm².

Next, after the resist mask RM is removed, at a step shown in FIG. 20, a nickel film ML having a thickness of about 200 nm is formed by using, for example, the sputtering method, so as to cover the semiconductor substrate 1 and heated at 300° C. for about several hundreds of seconds to form nickel silicide layers 37 and 47 mainly composed of Ni₂Si on the polysilicon gates 32 and 42, respectively.

At this time, since nickel is prevented from diffusing in the polysilicon gate 32 containing nitrogen, the nickel silicide layer 37 formed on the polysilicon gate 32 is thinner than the nickel silicide layer 47 formed on the polysilicon gate 42 containing no nitrogen.

Next, the unreacted nickel film ML is removed by wet etching using compound liquid of phosphoric acid and nitric acid or the like.

Then, by application of heat treatment at 500° C. for several hundreds of seconds, nickel in the nickel silicide layers 37 and 47 diffuses and the polysilicon gates 32 and 42 are silicided as a whole. As shown in FIG. 21, the nickel silicide layers 37 and 47 become FUSI gates 371 and 471, respectively, to complete MOS transistors 30 and 40.

At this time, due to the thick nickel silicide layer 47, the amount of nickel per unit volume in the FUSI gate 471 is larger than that in the FUSI gate 371.

### <D-2. Effects>

According to the method of manufacturing a semiconductor device in accordance with Fourth Embodiment as described above, in the manufacturing process of the MOS transistor 30 formed in the logic region, nitrogen ions are implanted into the polysilicon gate 32 and then the nickel silicide layer 37 mainly composed of Ni₂Si is formed on the polysilicon gate 32.

Here, since the transistor having small gate length or gate width has small gate volume, the amount of nickel which reacts with silicon relatively increases, resulting in a nickel-rich transistor. However, since nickel is prevented from diffusing in the polysilicon gate 32 containing nitrogen, the nickel silicide layer 37 is thinner than the nickel silicide layer 27 formed in the polysilicon gate 22 containing no nitrogen. When fully silicided by subsequent heat treatment, the amount of nickel contained in the FUSI gate 371 per unit volume is decreased. For this reason, in the MOS transistor 30, the FUSI gate 371 does not become nickel-rich.

As described above, since the threshold of the PMOS transistor becomes lower as the amount of nickel is increased and the threshold of the NMOS transistor becomes higher as the amount of nickel is increased, variation in the threshold occurs depending on the nickel-rich transistor or non-nickel-rich transistor and it is hard to control reaction ratio of nickel and silicon.

However, as described above, the reaction ratio of nickel and silicon is easily controlled by implanting nitrogen ions into only the gate of the transistor having a small gate length, gate width or gate height, which easily becomes nickel-rich, a state where the threshold varies among the transistors in the same logic region can be prevented.

In Fourth Embodiment, driving voltages of two kinds of MOS transistors disposed in the logic region and the I/O region are different from each other. However, when the manufacturing method in accordance with Fourth Embodiment is applied to the MOS transistors which have the same driving voltage, but have different gate widths due to different current driving forces, it is needless to say that variation in threshold can be prevented.

### E. Fifth Embodiment

As Fifth Embodiment of the present invention, a manufacturing process in a method of manufacturing a semiconductor device having MOS transistors 30A and 40A of different gate sizes on the common semiconductor substrate 1 will be described with reference to FIG. 22 to FIG. 24. Structure of the MOS transistors 30A and 40A is shown in FIG. 24.

### <E-1. Manufacturing Process>

In FIG. 22 to FIG. 24, the semiconductor substrate 1 is divided into the logic region and the I/O region. Steps for forming a MOS transistor 30A having a thin gate insulating film and a short gate length (FIG. 24) in the logic region and a MOS transistor 40A having a thick gate insulating film and a long gate length (FIG. 24) in the I/O region are shown in these figures.

Since transistor structure in the logic region and the I/O region shown in FIG. 22 is the same as the structure shown in FIG. 18, the same reference numerals are given to the similar components and overlapping description is not repeated.

At a step shown in FIG. 22, the semiconductor substrate 1 is covered with a resist mask RM and then, an opening OP for exposing the whole upper surface of the polysilicon gate 42 by photo lithography and dry etching.

Then, by implanting silicon ions into the polysilicon gate through the opening OP, the polysilicon gate 42 is amorphized to form an amorphous silicon gate 421.

The implantation energy at this time is set so that the implanted ions may not break through the polysilicon gate 42. For example, in a case of silicon ions, the implantation energy is set to about 5 keV and the dosage is set to about 2×10¹⁵/cm². When the implantation energy is 5 keV, implantation peak position is about 7 nm in depth. Thus, the implanted ions cannot break through the polysilicon gate 42 having the thickness of 100 nm. In place of silicon, P, Ar, Ge, As, Sb and In may be used. These ions may not be implanted deeper than a half of height of the polysilicon gate 42. Desirably, the implantation energy is set so that the implantation peak position is located at about one fifth of height of the polysilicon gate 42. An effective dose range of silicon ions is 5×10¹⁴ to 1×10¹⁶/cm².

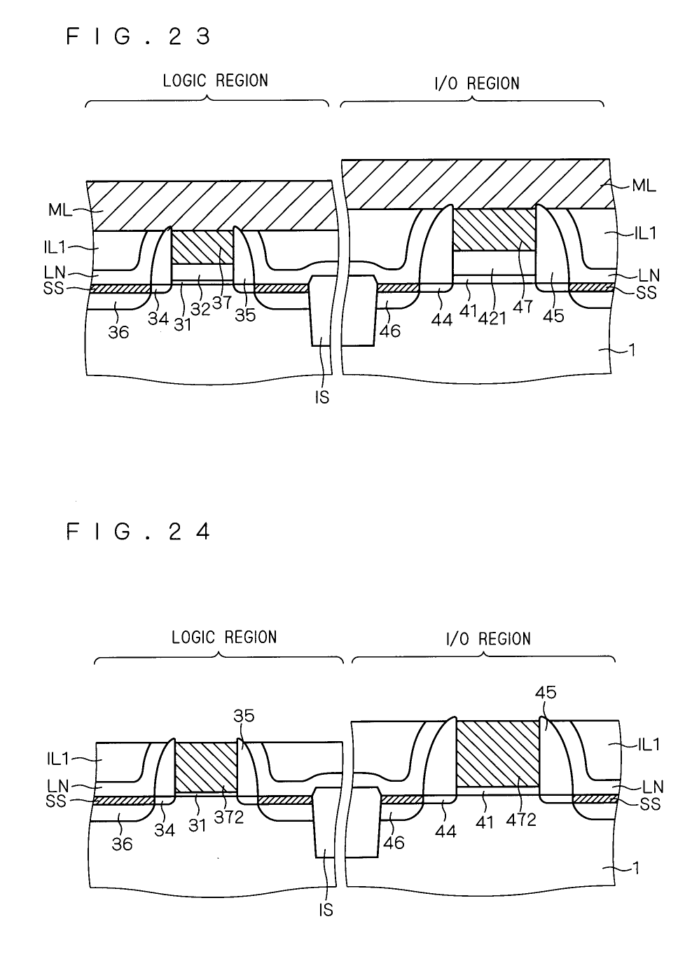

Next, after the resist mask RM is removed, at a step shown in FIG. 23, a nickel film ML having a thickness of about 200 nm is formed by using, for example, the sputtering method, so as to cover the semiconductor substrate 1 and heated at 300° C. for about several hundreds of seconds to form nickel silicide layers 37 and 47 mainly composed of Ni₂Si on the polysilicon gate 32 and the amorphous silicon gate 421, respectively.

Next, the unreacted nickel film ML is removed by wet etching using compound liquid of phosphoric acid and nitric acid or the like.

Then, by application of heat treatment at 500° C. for several hundreds of seconds, nickel in the nickel silicide layers 37 and 47 diffuses and the polysilicon gate 32 and the amorphous silicon gate 42 are silicided as a whole. As shown in FIG. 24, the nickel silicide layers 37 and 47 become FUSI gates 372 and 472, respectively, to complete the NMOS transistor 30A and the PMOS transistor 40A. Since subsequent steps are the same as the steps described with reference to FIG. 9, description thereof is not repeated.

### <E-2. Effects>

According to the method of manufacturing a semiconductor device in accordance with Fifth Embodiment, in the manufacturing process of the NMOS transistor 40A, silicon ions are implanted into the polysilicon gate 42 to form the amorphous silicon gate 421 and then, the nickel silicide layer 47 mainly composed of Ni₂Si is formed on the amorphous silicon gate 421.

In a case of polysilicon, diffusion state of silicide metal such as nickel can vary due to ununiformity of grain boundary. However, since the silicide metal is uniformly diffused because of amorphization caused by ion implantation, variation in transistor performance is suppressed.

Polysilicon can be also amorphized by implanting ions of P, Ar, Ge, As, Sb or In. Since this ion implantation is different from doping for setting the conductive type of the polysilicon gate and serves to control the diffusion of silicide metal, the implantation is performed immediately before the fully silicided process.

In a transistor using a High-k film as the gate insulating film and a FUSI gate as a gate electrode, if impurity of the same conductive type as the source-drain layer is introduced by so-called gate implantation, no effect brings about. Thus, since no trouble occurs even when a large amount of impurity of a different conductive type from the source-drain layer is introduced, the conductive type of ions implanted for amorphization need not be considered.

In the above-mentioned First to Fifth Embodiments, nickel is used as silicide metal. However, the present invention is not necessarily applied only to a case where nickel is used and can be applied to a case where, for example, titanium (Ti), manganese (Mn), Cobalt (Co), zirconium (Zr), molybdenum (Mo), palladium (Pd), tungsten (W) or platinum (Pt).

As described above, by introducing nitrogen into the polysilicon gate, silicide metal is prevented from diffusing and by introducing silicon into the polysilicon gate, amorphization is accelerated, thereby uniformly diffusing the silicide metal.

Use conditions are not limited to the mode in which, in the combination of the NMOS transistor and the PMOS transistor, or the logic region and the I/O region, nitrogen is introduced into only one of the transistors or the regions as described in First to Fifth Embodiments. In other words, nitrogen may be introduced into the polysilicon gates of all transistors or silicon may be introduced into the polysilicon gates of all transistors.

Thus, the effect of suppressing the diffusion of silicide metal in all transistors or the effect of accelerating amorphization in all transistors can be obtained.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a semiconductor device including an N-channel MOS transistor disposed in a first region on a semiconductor substrate and a P-channel MOS transistor disposed in a second region on said semiconductor substrate, the method comprising the steps of
(a) forming a first gate structure by selectively laminating a first high dielectric gate insulating film and a first polysilicon gate in said first region and then forming a first side-wall insulating film on each side face of said first high dielectric gate insulating film and said first polysilicon gate, and forming a second gate structure by selectively laminating a second high dielectric gate insulating film and a second polysilicon gate in said second region and then forming a second side-wall insulating film on each side face of said second high dielectric gate insulating film and said second polysilicon gate;
(b) forming a first impurity layer which makes a pair in a surface of said semiconductor substrate outside of side faces of said first gate structure and a second impurity layer which makes a pair in a surface of said semiconductor substrate outside of side faces of said second gate structure;
(c) covering said semiconductor substrate including said first and second gate structures with an insulating film and then removing said insulating film until upper surfaces of said first and second polysilicon gates are exposed;
(d) masking the surface of said second polysilicon gate and introducing one element selected from boron, nitrogen, oxygen, fluorine and germanium into said first polysilicon gate; and
(e) forming a silicide metal film so as to contact with the upper surfaces of said first and second polysilicon gates to fully silicide said first and second polysilicon gates.

2. The method of manufacturing a semiconductor device according to claim 1, wherein
said step (d) is performed after said step (c), and
includes the step of removing said insulating film until the upper surfaces of said first and second polysilicon gates are exposed and then, forming a first resist mask on which a first opening is patterned so that the upper surface of said first polysilicon gate is exposed and introducing the one element by ion implantation through said first opening.

3. The method of manufacturing a semiconductor device according to claim 2, the method further comprising the step of, after said step (d) and before said step (e):
(f) forming a second resist mask on which a second opening is patterned so that the upper surface of said second polysilicon gate is exposed and introducing one element selected from silicon, phosphorus, argon, germanium, arsenic, stibium and indium into said second polysilicon gate by ion implantation through said second opening.

4. The method of manufacturing a semiconductor device according to claim 3, wherein
said step (f) includes the step of making said second polysilicon gate thinner by etching through said second opening before said ion implantation through said second opening.

5. The method of manufacturing a semiconductor device according to claim 1, wherein
said step (a) includes the step of forming said first and second high dielectric gate insulating films of one of an HfO₂ film and an HfSiON film.

6. A method of manufacturing a semiconductor device including a first MOS transistor disposed in a first region on a semiconductor substrate and a second MOS transistor disposed in a second region on said semiconductor substrate, the method comprising the steps of
(a) forming a first gate structure by selectively laminating a first high dielectric gate insulating film and a first polysilicon gate in said first region and then forming a first side-wall insulating film on each side face of said first high dielectric gate insulating film and said first polysilicon gate, and forming a second gate structure by selectively laminating a second high dielectric gate insulating film and a second polysilicon gate in said second region and then forming a second side-wall insulating film on each side face of said second high dielectric gate insulating film and said second polysilicon gate;
(b) forming a first impurity layer which makes a pair in a surface of said semiconductor substrate outside of side faces of said first gate structure, and forming a second impurity layer which makes a pair in a surface of said semiconductor substrate outside of side faces of said second gate structure;
(c) covering said semiconductor substrate including said first and second gate structures with an insulating film and then removing said insulating film until upper surfaces of said first and second polysilicon gates are exposed;
(d) masking the surface of said second polysilicon gate and introducing one element selected from boron, nitrogen, oxygen, fluorine and germanium into said first polysilicon gate; and
(e) forming a silicide metal film so as to contact with the upper surfaces of said first and second polysilicon gates to fully silicide said first and second polysilicon gates, wherein
said step (a) includes the step of making at least one of gate length and gate width of said first polysilicon gate smaller than at least one of gate length and gate width of said second polysilicon gate.

7. The method of manufacturing a semiconductor device according to claim 6, wherein
said step (d) is performed after said step (c), and
includes the step of removing said insulating film until the upper surfaces of said first and second polysilicon gates are exposed, then forming a first resist mask on which a first opening is patterned so that the upper surface of said first polysilicon gate is exposed, and introducing said one element by ion implantation through said first opening.

8. The method of manufacturing a semiconductor device according to claim 7, the method further comprising the step of, after said step (d) and before said step (e):
(f) forming a second resist mask on which a second opening is patterned so that the upper surface of said second polysilicon gate is exposed, and introducing one element selected from silicon, phosphorus, argon, germanium, arsenic, stibium and indium into said second polysilicon gate by ion implantation through said second opening.

9. The method of manufacturing a semiconductor device according to claim 8, wherein
said step (f) includes the step of making said second polysilicon gate thinner by etching through said second opening before said ion implantation through said second opening.

10. The method of manufacturing a semiconductor device according to claim 6, wherein
said first region corresponds to a logic region where a logic circuit is disposed,
said second region corresponds to an I/O region where an input/output circuit is disposed, and
said step (a) includes the step of making said first high dielectric gate insulating film thinner than said second high dielectric gate insulating film.

11. The method of manufacturing a semiconductor device according to claim 6, wherein
said step (a) includes the step of forming said first and second high dielectric gate insulating films of one of an HfO₂ film and an HfSiON film.

12. A method of manufacturing a semiconductor device including an N-channel MOS transistor disposed in a first region on a semiconductor substrate and a P-channel MOS transistor disposed in a second region on said semiconductor substrate, the method comprising the steps of
(a) forming a first gate structure by selectively laminating a first high dielectric gate insulating film and a first polysilicon gate in said first region and then forming a first side-wall insulating film on each side face of said first high dielectric gate insulating film and said first polysilicon gate, and forming a second gate structure by selectively laminating a second high dielectric gate insulating film and a second polysilicon gate in said second region and then forming a second side-wall insulating film on each side face of said second high dielectric gate insulating film and said second polysilicon gate;
(b) forming a first impurity layer which makes a pair in a surface of said semiconductor substrate outside of side faces of said first gate structure, and forming a second impurity layer which makes a pair in a surface of said semiconductor substrate outside of side faces of said second gate structure;
(c) covering said semiconductor substrate including said first and second gate structures with an insulating film and then removing said insulating film until upper surfaces of said first and second polysilicon gates are exposed;
(d) masking the surface of said first polysilicon gate and introducing one element selected from silicon, phosphorus, argon, germanium, arsenic, stibium and indium into said second polysilicon gate; and
(e) forming a silicide metal film so as to contact with the upper surfaces of said first and second polysilicon gates to fully silicide said first and second polysilicon gates.

13. The method of manufacturing a semiconductor device according to claim 12, wherein
said step (d) is performed after said step (c), and
includes the step of removing said insulating film until the upper surfaces of said first and second polysilicon gates are exposed, then forming a resist mask on which an opening is patterned so that the upper surface of said second polysilicon gate is exposed, and introducing said one element by ion implantation through said opening.

14. The method of manufacturing a semiconductor device according to claim 12, wherein
said step (a) includes the step of forming said first and second high dielectric gate insulating films of one of an HfO₂ film and an HFSiON film.

15. A method of manufacturing a semiconductor device including a first MOS transistor disposed in a first region on a semiconductor substrate and a second MOS transistor disposed in a second region on said semiconductor substrate, the method comprising the steps of
(a) forming a first gate structure by selectively laminating a first high dielectric gate insulating film and a first polysilicon gate in said first region and then forming a first side-wall insulating film on each side face of said first high dielectric gate insulating film and said first polysilicon gate, and forming a second gate structure by selectively laminating a second high dielectric gate insulating film and a second polysilicon gate in said second region and then forming a second side-wall insulating film on each side face of said second high dielectric gate insulating film and said second polysilicon gate;
(b) forming a first impurity layer which makes a pair in a surface of said semiconductor substrate outside of side faces of said first gate structure, and forming a second impurity layer which makes a pair in a surface of said semiconductor substrate outside of side faces of said second gate structure;
(c) covering said semiconductor substrate including said first and second gate structures with an insulating film, and then removing said insulating film until upper surfaces of said first and second polysilicon gates are exposed;
(d) masking the surface of said first polysilicon gate and introducing one element selected from silicon, phosphorus, argon, germanium, arsenic, stibium and indium into said second polysilicon gate; and
(e) forming a silicide metal film so as to contact with the upper surfaces of said first and second polysilicon gates to fully silicide said first and second polysilicon gates, wherein
said step (a) includes the step of making at least one of gate length and gate width of said first polysilicon gate smaller than at least one of gate length and gate width of said second polysilicon gate.

16. The method of manufacturing a semiconductor device according to claim 15, wherein
said step (d) is performed after said step (c), and
includes the step of removing said insulating film until the upper surfaces of said first and second polysilicon gates are exposed, then forming a resist mask on which an opening is patterned so that the upper surface of said second polysilicon gate is exposed, and introducing said one element by ion implantation through said opening.

17. The method of manufacturing a semiconductor device according to claim 15, wherein
said first region corresponds to a logic region where a logic circuit is disposed,
said second region corresponds to an I/O region where an input/output circuit is disposed, and
said step (a) includes the step of making said first high dielectric gate insulating film thinner than said second high dielectric gate insulating film.

18. The method of manufacturing a semiconductor device according to claim 15, wherein
said step (a) includes the step of forming said first and second high dielectric gate insulating films of one of an HfO₂ film and an HfSiON film.

19. A method of manufacturing a semiconductor device including a MOS transistor disposed on a semiconductor substrate, the method comprising the steps of
(a) forming a gate structure by selectively laminating a high dielectric gate insulating film and a polysilicon gate on a main surface of said semiconductor substrate, and then forming a side-wall insulating film on each side face of said high dielectric gate insulating film and said polysilicon gate;
(b) forming an impurity layer which makes a pair in a surface of said semiconductor substrate outside of side faces of said gate structure;
(c) covering said semiconductor substrate including said gate structure with an insulating film, and then removing said insulating film until an upper surface of said polysilicon gate is exposed;
(d) introducing one element selected from silicon and nitrogen molecule into said polysilicon gate; and
(e) forming a silicide metal film so as to contact with the upper surface of said polysilicon gate to fully silicide said polysilicon gate.

20. The method of manufacturing a semiconductor device according to claim 19, wherein
said step (a) includes the step of forming said high dielectric gate insulating film of one of an HfO₂ film and an HFSiON film.
